(19) United States
(12) Patent Application Publication
(10) Pub. No.: US 2013/0221813 A1
(43) Pub. Date: Aug. 29, 2013

(54) FRAME FOR CABINET, IN PARTICULAR FOR A SWITCHGEAR CABINET

(71) Applicant: Christof Maisch, Gaggenau (DE)

(72) Inventor: Christof Maisch, Gaggenau (DE)

(73) Assignee: Protektorwerk Florenz Maisch GmbH & Co. KG, Gaggenau (DE)

(21) Appl. No.: 13/813,164

(22) PCT Filed: Jul. 15, 2011
(86) PCT No.: PCT/EP2011/003553

§ 371 Date: May 16, 2013

(30) Foreign Application Priority Data
Aug. 4, 2010 (DE) 10 2010 033 319.0

(51) Int. Cl. H05K 7/18; A47B 87/00

(52) U.S. Cl. CPC H05K 7/18; A47B 87/00
USPC 312/107

(57) ABSTRACT

The invention describes a cabinet profile of a cabinet, in particular a switchgear cabinet profile of a switchgear cabinet. The cabinet profile comprises an elongate metal hollow profile which has a plurality of wall sections, which adjoin one another, in the circumferential direction, wherein one or more openings are formed at least in some of the wall sections. The one or more openings are formed at least in a wall section which faces the outer face of the cabinet when the cabinet profile is in the mounted state, wherein at least a portion of the one or more openings is covered by at least one plastic cover which is connected to the hollow profile. The invention also describes a cabinet, in particular a switchgear cabinet, having at least one horizontally running cabinet profile of this kind.

The present invention relates to a cabinet section, in particular to a switch cabinet section of a switch cabinet, comprising an elongated metal hollow section which has a plurality of mutually adjacent wall sections in the peripheral direction, with one or more openings being formed in at least one part of the wall section. The invention is furthermore directed to a cabinet, in particular to a switch cabinet, having a frame-like base body formed from a plurality of cabinet sections, wherein the cabinet sections are connected to one another by side walls and by a top plate and/or a base plate for forming a cabinet housing, in particular a closed cabinet housing, and wherein a cabinet door is provided at the front side of the cabinet which is formed in a manner capable of sealing by a peripheral seal with respect to a cabinet section extending horizontally in the upper region of the cabinet door and/or in the lower region of the cabinet door.

Cabinet sections of the initially named kind are in particular used for forming switch cabinets. The cabinet sections are in this respect usually made completely from metal to ensure the required stiffness of the switch cabinet. Furthermore, the cabinet sections have to be designed so that, when the cabinet is completely installed, a seal to the outside is provided against moisture, in particular protection against splash water. The wall sections of the cabinet sections which face outwardly to the environment are therefore usually formed with a full surface, i.e. without openings, to ensure the desired seal. The wall sections facing toward the interior of the cabinet are, in contrast, usually provided with openings to allow the fastening of elements of the switch cabinet.

Since at least the outwardly disposed wall sections are formed with a full surface, the manufacturing costs as well as the weight of a switch cabinet section are relatively high since the manufacturing costs are predominantly determined by the material costs.

It is an object of the present invention to provide a cabinet section, in particular a switch cabinet section, as well as a cabinet, which can be manufactured more inexpensively.

Starting from a cabinet section of the initially named kind, this object is satisfied in accordance with the invention in that the one or more openings are formed at least in a wall section which in the installed state of the cabinet section faces toward the outer side of the cabinet and in that at least some of the one or more openings is/are covered by at least one plastic cover connected to the hollow section.

In accordance with the invention, openings are thus admittedly formed in the wall sections which ultimately face outwardly in the installed state and must therefore satisfy the required sealing effect to achieve a material saving and thus a cost saving as well as a weight reduction; at the same time the required seal-tightness is achieved by the provided plastic cover. The cabinet section in accordance with the invention thus comprises a hybrid construction of metal and plastic and combines advantages of the two materials used in an ideal manner. In particular the required stiffness remains due to the base structure comprising metal.

To achieve a linguistic simplification, in the present application, instead of the expression “one or more openings”, frequently the simple plural form “openings” will be used. It is, however, explicitly pointed out that the invention also covers embodiments in which only one opening is formed in the wall section facing toward the outer side of the cabinet.

The openings formed in the wall section preferably form weight reduction openings which are so large that a clear weight reduction of the hollow section is achieved with respect to a corresponding hollow section without weight reduction openings, in particular a weight reduction by at least 4%, preferably by more than 8%. The weight reduction openings are in particular formed and arranged in the wall section in this respect such that the inner space of the cabinet is accessible from the outside through the weight reduction openings without a plastic cover with an installed cabinet section. Moisture can generally also enter into the inner space of the cabinet in an unwanted manner due to this accessibility, which is, however, prevented In accordance with the invention by the plastic cover with only a minimal weight increase.

In accordance with a further advantageous embodiment of the invention, in the installed state of the cabinet section, wall sections which face toward the inner space of the cabinet and in which fastening openings for elements to be arranged within the cabinet are formed. The fastening openings can in particular be in communication with the weight reduction openings so that moisture could generally enter into the inner space of the cabinet in an unwanted manner via the outwardly disposed weight reduction openings and subsequently the inwardly disposed fastening openings. This is, however, prevented in accordance with the invention by the plastic cover.

In accordance with an advantageous embodiment of the invention, the plastic cover is sealingly connected, in particular in a manner resistant to splash water, to the hollow section. The connection can in this respect, for example, take place by a bonding, latching, clamping, a plug connection or by foaming. The plastic cover can thus, for example, also be pushed into a corresponding groove in the hollow section.

A plurality of openings are preferably covered by a common plastic cover. This in particular reduces the manufacturing effort on the joining of the two parts.

It is generally possible that at least one opening extends over the total length of the hollow section or that a plurality of openings are provided distributed over the length and/or the periphery of the hollow section. It is only important in this respect that the outwardly facing openings, which have to be covered with respect to the interior of the hollow section and with respect to the interior of the switch cabinet, are provided with a corresponding plastic cover.

In accordance with a further advantageous embodiment of the invention, the plastic cover contacts the material of the hollow section in the region of the openings. A direct cover and sealing of the openings is thereby achieved. It is, however, generally also possible that the plastic cover is spaced apart from the material of the hollow section in the region of the openings as long as the desired sealing toward the outside is ensured despite this spacing.

In accordance with a further preferred embodiment of the invention, the openings extend over two mutually adjacent wall sections. For example, the hollow section can have a substantially L-shaped cross-section which is in particular defined by two such mutually adjacent wall sections. The openings can thus, for example, be formed in two mutually adjacent wall sections of the hollow section which include an outwardly open angle, in particular an angle of approximately 90°. The plastic cover can in this respect be formed as a plastic bracket which is inserted into the outwardly open angle of the hollow section. In this respect, the plastic bracket can in particular include two limbs which are arranged at the same angle to one another as the two mutually adjacent wall sections. A particularly intimate connection of the hollow section and the plastic cover is thereby achieved.

In accordance with a further advantageous embodiment of the invention, an in particular strip-shaped nose is provided, in particular molded, at at least one of the two limbs and extends in the longitudinal direction of the plastic bracket and projects obliquely from the limb. This strip-shaped nose can form an additional splash protection or a kind of channel to lead off liquid.

The plastic cover is advantageously made as an injection molded part. A manufacture by extrusion is also possible.

A cabinet formed in accordance with the invention, in particular a switch cabinet formed in accordance with the invention, is characterized with respect to an initially named cabinet in that at least one of the horizontally extending cabinet sections is formed by a cabinet section formed In accordance with the invention.

Further advantageous embodiments are set forth in the dependent claims.

The invention will be described in more detail in the following with reference to embodiments and to the drawings; there are shown in these:

FIG. 1 a perspective representation of a hollow section of a cabinet section formed in accordance with the invention.

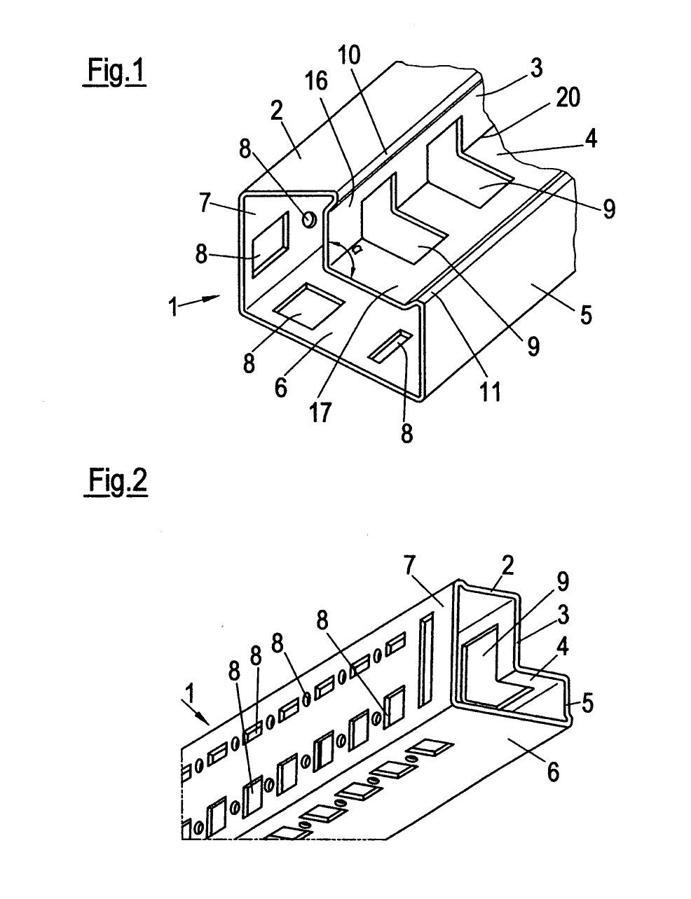

FIG. 2 a slightly modified version of the hollow section in accordance with FIG. 1 in a perspective representation obliquely from below;

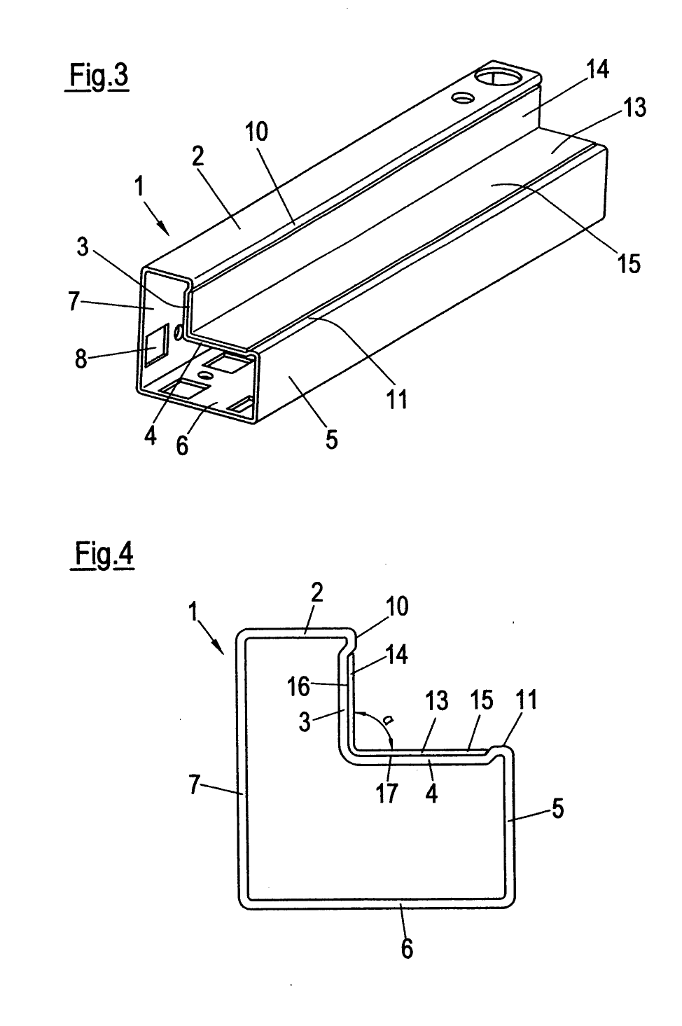

FIG. 3 a cabinet section formed in accordance with the invention with a hollow section in accordance with FIG. 1 and with a plastic cover in accordance with the invention;

FIG. 4 the cabinet section in accordance with FIG. 3 in cross-section;

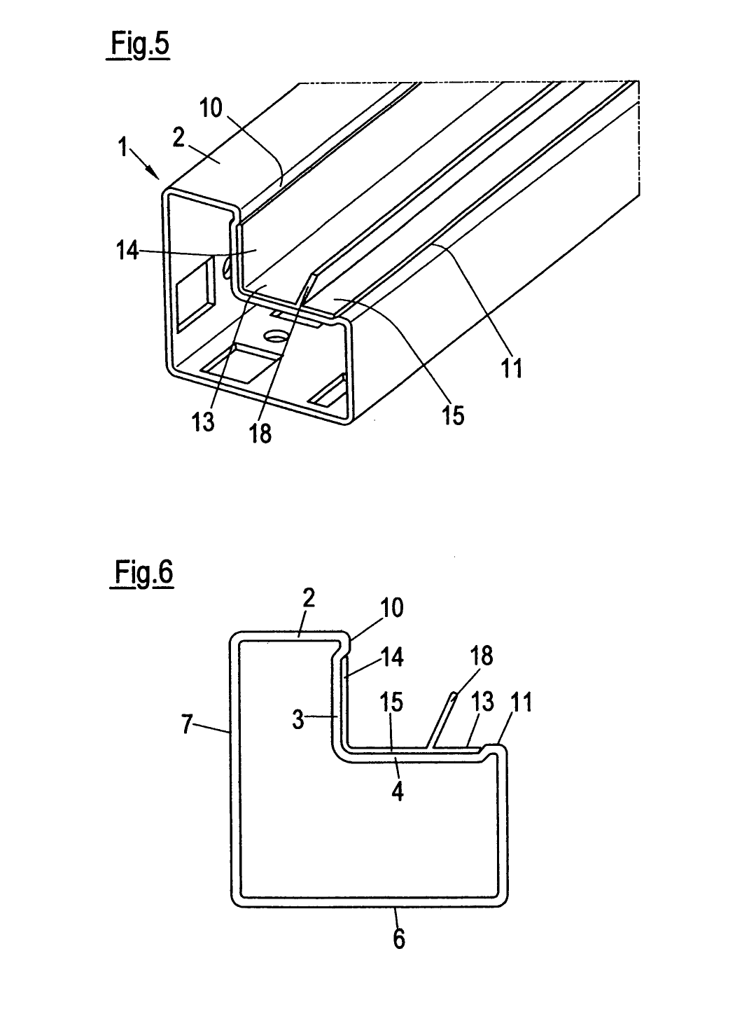

FIG. 5 a further cabinet section in accordance with the invention with a modified plastic cover in a perspective representation;

FIG. 6 the cabinet section in accordance with FIG. 5 in cross-section;

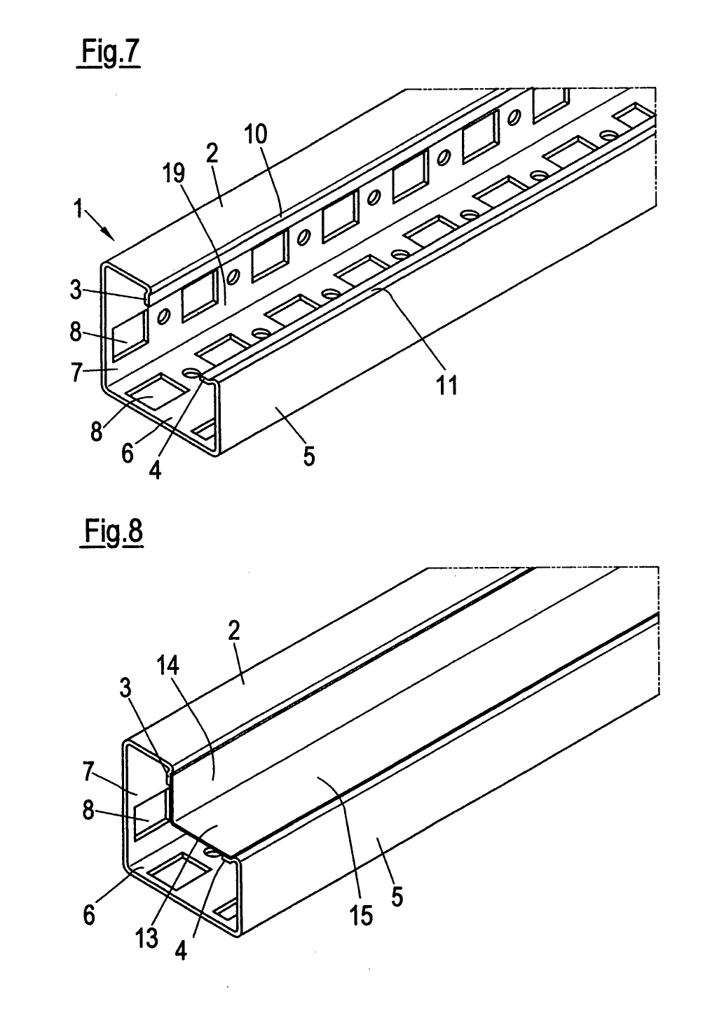

FIG. 7 a further embodiment of a hollow section in accordance with the invention;

FIG. 8 a further embodiment of a cabinet section in accordance with the invention with a hollow section in accordance with FIG. 7;

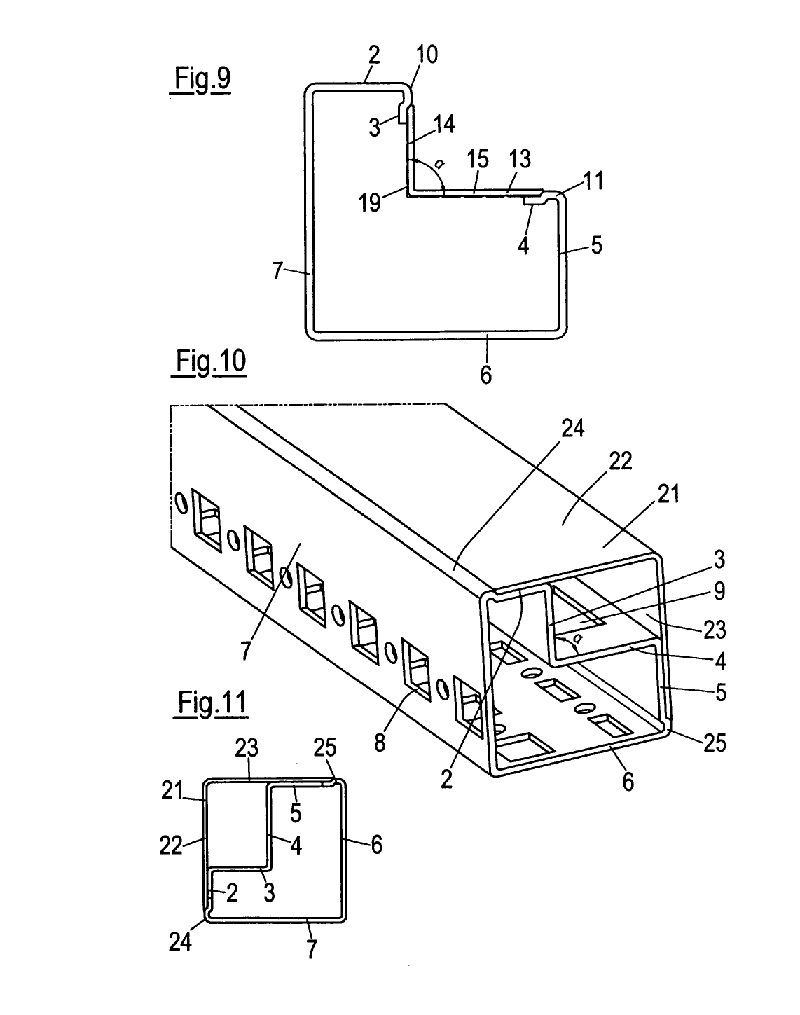

FIG. 9 the cabinet section in accordance with FIG. 8 in cross-section;

FIG. 10 a further embodiment of the invention;

FIG. 11 the cabinet section in accordance with FIG. 10 in cross-section;

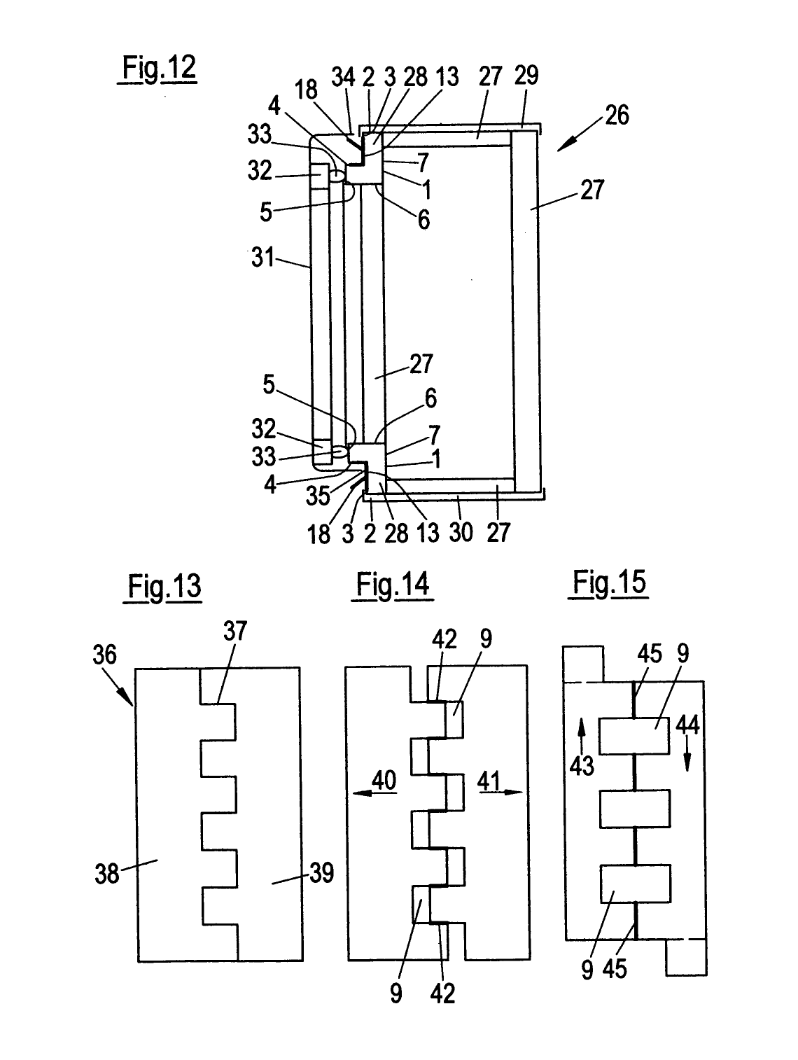

FIG. 12 a greatly simplified longitudinal section through a switch cabinet formed in accordance with the invention;

FIG. 13 a metal element for manufacturing a hollow section for a cabinet section formed in accordance with the invention;

FIG. 14 an intermediate step for manufacturing a cabinet section formed in accordance with the invention from a metal section in accordance with FIG. 13; and

FIG. 15 an intermediate step in accordance with a further embodiment of the invention for manufacturing a cabinet section formed in accordance with the invention.

FIGS. 1 and 2 each show an L-shaped metal hollow section 1 which includes a plurality of wall sections 2 to 7 mutually adjacent in the peripheral direction. The wall sections 2 to 7 are each made substantially planar and are mutually angled in order ultimately to produce the L-shaped cross-section of the hollow section 1.

Respective openings 8, 9 are formed in the wall sections 3, 4 and 6, 7, with the openings 8 being located in the wall sections 6, 7 which face toward the interior of the cabinet with an installed cabinet section, whereas the openings 9 are formed in the wall sections 3, 4 which face toward the outer side of the cabinet in the installed state of the cabinet section. This will be explained in even more detail within the framework of the application with reference to FIG. 12.

The wall sections 3, 4 are substantially perpendicular to one another and thus include an outwardly open angle α.

The wall sections 3, 4 have respective projections 10, 11 which extend in the longitudinal direction at their outwardly disposed longitudinal edges so that the regions of the wall sections 3, 4 disposed between the projections 10 and a connection line 20 or between the projection 11 and the connection line 20 are set back with respect to the projections 10, 11 and each form a receiver 16, 17 for a plastic cover still to be described.

A plastic cover 13 which is formed as a plastic bracket whose two limbs 14, 15 lie areally on the wall sections 3, 4 are inserted into the angle α in FIG. 3. The openings 9 are completely covered by the plastic cover 13 so that the plastic cover 13 forms a seal for the hollow section 1 with respect to the openings 9. Since, as already mentioned, the wall sections 3, 4 face outwardly in the installed state of the cabinet section, the hollow section 1 is thus outwardly sealed, for example protected against splash water, in the installed state.

The arrangement of the plastic cover 13 at the wall sections 3, 4 can be seen again more precisely in FIG. 4. It becomes clear from FIG. 4 that the limbs 14, 15 of the plastic cover 13 come to lie in the receivers 16, 17 and extend substantially flush with the projections 10,11.

The embodiment shown in FIGS. 5 and 6 differ from the embodiment in accordance with FIGS. 1 to 4 only in that the plastic cover 13 additionally has a strip-shaped nose 18 at its limb 15 which is in particular made in one piece with the plastic cover 13. The strip-shaped nose 18 can, for example, serve as a drain channel for liquids when the cabinet section is installed, for example, in a switch cabinet, as will be described later with reference to FIG. 12.

The strip-shaped nose 8 extends over the total length of the plastic cover 13 and projects obliquely from the limb 15, as can be recognized from FIG. 5 and in particular also from the cross-section in accordance with FIG. 6.

Openings 9 which are covered and sealed by the plastic cover 13 are also formed beneath the plastic cover 13 in the embodiment in accordance with FIGS. 5 and 6.

The embodiment in accordance with FIGS. 7 to 9 only differs from the previously shown embodiments in that not a plurality of mutually spaced apart openings 9 are formed in the wall sections 3, 4, but that rather material regions of the wall sections 3, 4 extending over the total length of the hollow section 1 are removed so that ultimately a single large opening 19 is formed between the projections 10, 11 which extends over the total length of the hollow section 1. Although the wall sections 3, 4 are thus only present in rudimentary form and are in particular no longer connected to one another directly via a connection line 20, in accordance with the invention the remaining wall sections 3, 4 continue to enclose an angle α as is in particular indicated by broken lines in FIG. 9.

In accordance with FIGS. 8 and 9, the opening 19 is completely covered by the plastic cover 13 in that the free ends of the limbs 14, 15 of the plastic cover 13 are connected, for example bonded, to the remaining regions of the wall sections 3, 4. A sealing of the hollow section 1 outwardly in the installed state is thus also achieved in this embodiment.

In the embodiment shown in FIGS. 10 and 11, the hollow section 1 is formed identical with the hollow section of FIG. 2. In a modification of the embodiments previously described, a plastic cover 21 is provided which is admittedly in turn formed as a plastic bracket, but is not inserted into the angle α between the wall sections 3, 4, but the limbs 22, 23 of the plastic cover 21 rather contact the wall sections 2, 5 of the hollow section 1. To maintain a flush transition, projections 24, 25 are in this case formed at the ends of the wall sections 2, 5 at the side of the outer edge, with the respective upper sides of the limbs 22, 23 of the plastic cover 21 in each case adjoining said projections in a flush manner, as can be recognized from FIGS. 10 and 11.

It is understood that the plastic covers 13, 21 can also include an additional strip-shaped nose 18, as is shown in FIGS. 5 and 6, in the embodiments in accordance with FIGS. 7 to 11.

FIG. 12 shows a switch cabinet 26 which includes a base body comprising a plurality of cabinet sections 27, which are, for example screwed or welded to one another, as well as cabinet sections 28 formed in accordance with the invention. The cabinet sections 27, 28 are connected to one another by a top plate 29 and a base plate 30 and side walls, not shown, so that a stable cabinet housing is created.

A cabinet door 31 which is shown in the closed state is arranged at the front side of the switch cabinet 26 shown at the left in FIG. 12. A peripheral section 32 is provided at the inner side of the cabinet door 31 and a peripheral seal 33 is arranged at it for sealing the cabinet door 31.

The seal 33 contacts the wall sections 5 of the cabinet sections 28 in a sealing manner in each case in the upper and lower regions of the switch cabinet 36 so that the wall sections 5 each form sealing surfaces of the cabinet sections 28.

As can be recognized from FIG. 12, the cabinet sections 28 are arranged so that the wall sections 6, 7 are directed toward the interior of the switch cabinet 26, whereas the wall sections 2, 3, 4, 5 face outwardly. While the upwardly facing wall section 2 of the upwardly disposed cabinet section 28 is covered by the top plate 29 and is thus, for example, protected against moisture from the outside, the wall sections 3, 4 are exposed to moisture, for example rain, penetrating from the outside with an open cabinet door 31. Even with a closed cabinet door 31, moisture can penetrate to the wall sections 3, 4 of the cabinet section 28 via a gap 34 between the upper edge of the cabinet door 31 and the top plate 29. Since the openings 9 or the opening 19 are/is located in the wall sections 3, 4 for reducing the material, the cabinet sections 28 are provided with plastic covers 13 to achieve a sealing of the openings 9, 19 and thus reliably to prevent a penetration of moisture into the interior of the switch cabinet 26.

In addition, moisture penetrating via the gap 34 is led off by the obliquely extending strip-shaped nose 18 at the upper cabinet section 28 in the manner of a gutter so that the seal 33 is relieved and no moisture can collect in the region of the seal 33. It is advantageous for this purpose if the strip-shaped nose 18 is slightly inclined with respect to the horizontal arrangement to allow a lateral flowing off of the moisture.

An additional splash protection is formed by the strip-shaped nose 18 provided at the lower cabinet section 28 and reliably protects a gap 35 present between the lower edge of the cabinet door 31 and the lower cabinet section 28 from splash water, for example by rain hitting the ground.

The openings 9 and 19 respectively in the hollow sections 1 can generally be formed in a usual shape by stamping out. It is, however, also possible that the openings are formed without material loss as will be described in the following in brief with reference to FIGS. 13 to 15.

FIG. 13 shows a metal sheet 36 into which a meandering incision 37 is introduced to divide the metal sheet 36 into two longitudinal sections 38, 39. The two longitudinal sections 38, 39 are subsequently moved apart in accordance with two arrows 40, 41, as is shown in FIG. 14. In a first embodiment, the two longitudinal cross-sections 38, 39 are only moved apart so far until they reach the positions shown in FIG. 14. In this position, the two longitudinal sections 38, 39 are connected to one another, for example welded to one another, along their edges 42 contacting one another transversely to the longitudinal section of the longitudinal sections 38, 39.

In an alternative embodiment, the longitudinal sections 38, 39 can be drawn apart completely, i.e. so far that they no longer form any undercuts in the longitudinal direction. Subsequently, the longitudinal sections 38, 39 are pushed toward one another in accordance with arrows 43, 44 until they each reach the positions shown in FIG. 15. In this state, the mutually contacting longitudinal edges 45 are connected to one another, for example welded to one another.

In both embodiments, openings 9 are formed without corresponding material being lost in this respect.

The mutually connected longitudinal sections 38, 39 connected in this manner can subsequently be shaped to form the desired hollow sections 1.

The invention was described by way of example with reference to cabinet sections, in particular switch cabinet sections, with which corresponding cabinets, in particular switch cabinets, can be manufactured. Generally, a section formed in accordance with the invention can be used wherever a high stiffness and seal-tightness toward moisture is equally required, for example in display refrigerators. An ideal cost-benefit function is achieved by the sharing of these two functions in an embodiment of the section having different materials since the required stiffness is achieved by the metal region and the desired seal-tightness with a reduced metal quantity is achieved by the plastic cover.

### Reference Numeral List

1 hollow section
2 wall section
3 wall section
4 wall section
5 wall section
6 wall section
7 wall section
8 openings
9 openings
10 projection
11 projection
13 plastic cover
14 limb
15 limb
16 receiver
17 receiver
18 strip-shaped nose
19 opening
20 connection line
21 plastic cover
22 limb
23 limb
24 projection
25 projection
26 switch cabinet
27 cabinet sections
28 cabinet section
29 top plate
30 base plate
31 cabinet door
32 section
33 seal
34 gap
35 gap
36 metal sheet
37 meandering incision
38 longitudinal section
39 longitudinal section
40 arrow
41 arrow
42 edge
43 arrow
44 arrow
45 longitudinal edge
α angle

1-19. (canceled)

20. A cabinet section of a cabinet, comprising an elongated metal hollow section (1) which has a plurality of mutually adjacent wall sections (2-7) in the peripheral direction, wherein one or more openings (8, 9, 19) are formed in at least one part of the wall sections (3, 4, 6, 7),
wherein the one or more openings (8, 9, 19) are formed in at least one wall section (3, 4) which faces toward the outer side of the cabinet (26) in the installed state of the cabinet section (28),
wherein at least some of the one or more openings (9, 19) are covered by at least one plastic cover (13, 21) connected to the hollow section (1);
wherein the openings (9, 19) formed in the wall section (3, 4) form weight reduction openings which are so large that a clear weight reduction of the hollow section (1) is achieved with respect to a corresponding hollow section without weight reduction openings (9, 19); and
wherein the weight reduction openings (9, 19) are formed and arranged in the wall section (3, 4) so that the inner space of the cabinet (26) is accessible from the outside through the weight reduction openings (9, 19) without a plastic cover (13, 21) with an installed cabinet section (28).

21. A cabinet section in accordance with claim 20, wherein the cabinet section is a switch cabinet section of a switch cabinet (26).

22. A cabinet section in accordance with claim 20, wherein the weight reduction openings (9, 19) formed in the wall section (3, 4) are formed as so large that a weight reduction of the hollow section (1) is achieved with respect to a corresponding hollow section without weight reduction openings (9, 19) by at least 4%.

23. A cabinet section in accordance with claim 22, wherein a weight reduction of the hollow section (1) by more than 8% is achieved.

24. A cabinet section in accordance with claim 20, wherein wall sections (6, 7) are provided, wherein fastening openings (8) for elements to be arranged within the cabinet (26) are formed in the wall sections (6, 7), and wherein the fastening openings face toward the inner space of the cabinet (26) in the installed state of the cabinet section (28).

25. A cabinet section in accordance with claim 24, wherein the fastening openings (8) are in communication with the weight reduction openings (9, 19).

26. A cabinet section in accordance with claim 20, wherein the plastic cover (13, 21) is connected in a sealing manner to the hollow section (1).

27. A cabinet section in accordance with claim 26, wherein the plastic cover (13, 21) is connected to the hollow section (1) in a seal-tight manner against splash water.

28. A cabinet section in accordance with claim 20, wherein the plastic cover (13, 21) is bonded, latched, clamped, foamed or plug-connected to the hollow section (1).

29. A cabinet section in accordance with claim 20, wherein a plurality of openings (9) are covered by a common plastic cover (13).

30. A cabinet section in accordance with claim 20, wherein the at least one opening (19) extends over the total length of the hollow section (1).

31. A cabinet section in accordance with claim 20, wherein a plurality of openings (9) are provided distributed over the length and/or the periphery of the hollow section (1).

32. A cabinet section in accordance with claim 20, wherein the plastic cover (13) contacts the material of the hollow section (1) in the region of the openings (9, 19).

33. A cabinet section in accordance with claim 20, wherein the plastic cover (21) is spaced apart from the material of the hollow section (1) in the region of the openings (9, 19).

34. A cabinet section in accordance with claim 20, wherein the openings (9, 19) extend beyond two mutually adjacent wall sections (3, 4).

35. A cabinet section in accordance with claim 20, wherein the hollow section (1) has a substantially L-shaped cross-section.

36. A cabinet section in accordance with claim 20, wherein the openings (9, 19) are formed in two mutually adjacent wall sections (3, 4) of the hollow section (1) which include an outwardly open angle (α).

37. A cabinet section in accordance with claim 36, wherein the outwardly open angle (α) includes an angle of approximately 90°.

38. A cabinet section in accordance with claim 36, wherein the plastic cover (13) is made as a plastic bracket which is inserted into the outwardly open angle (α) of the hollow section (1).

39. A cabinet section in accordance with claim 38, wherein the plastic bracket (13) includes two limbs (14, 15) which are arranged at the same angle (α) toward one another as the two mutually adjacent wall sections (3, 4).

40. A cabinet section in accordance with claim 39, wherein a nose (18) is provided at at least one of the two limbs (14, 15) and extends in the longitudinal direction of the plastic bracket and projects obliquely from the limb (15).

41. A cabinet section in accordance with claim 40, wherein the nose (18) is a strip-shaped nose.

42. A cabinet section in accordance with claim 40, wherein the nose is molded to at least one of the two limbs (14, 15).

43. A cabinet section in accordance with claim 20, wherein the plastic cover (13, 21) is formed as an injection molded part or by extrusion.

44. A cabinet having a frame-like base body formed from a plurality of cabinet sections (27, 28), wherein the cabinet sections (27, 28) are connected to one another by side walls and/or by a top plate (29) and/or by a base plate (30) for forming a cabinet housing;
and wherein a cabinet door (31) is provided at the front side of the cabinet (26) which is formed in a sealable manner by a peripheral seal (33) with respect to a cabinet section (28) extending horizontally in the upper region of the cabinet door (31) and/or in the lower region of the cabinet door (31),
wherein at least one of the horizontally extending cabinet sections (28) is formed comprising an elongated metal hollow section (1) which has a plurality of mutually adjacent wall sections (2-7) in the peripheral direction, wherein one or more openings (8, 9, 19) are formed in at least one part of the wall sections (3, 4, 6, 7), wherein the one or more openings (8, 9, 19) are formed in at least one wall section (3, 4) which faces toward the outer side of the cabinet (26) in the installed state of the cabinet section (28),
wherein at least some of the one or more openings (9, 19) are covered by at least one plastic cover (13, 21) connected to the hollow section (1);
wherein the openings (9, 19) formed in the wall section (3, 4) form weight reduction openings which are so large that a clear weight reduction of the hollow section (1) is achieved with respect to a corresponding hollow section without weight reduction openings (9, 19); and
wherein the weight reduction openings (9, 19) are formed and arranged in the wall section (3, 4) so that the inner space of the cabinet (26) is accessible from the outside through the weight reduction openings (9, 19) without a plastic cover (13, 21) with an installed cabinet section (28).

45. A cabinet in accordance with claim 44, wherein the cabinet is a switch cabinet (26).

46. A cabinet in accordance with claim 44, wherein the cabinet housing is a closed cabinet housing.
